(19) United States
(12) Patent Application Publication
(10) Pub. No.: US 2023/0265559 A1
(43) Pub. Date: Aug. 24, 2023

(54) METHOD FOR FORMING A COMPOSITE METAL FILM USING ATOMIC LAYER DEPOSITION

(71) Applicant: INDUSTRY-UNIVERSITY COOPERATION FOUNDATION HANYANG UNIVERSITY ERICA CAMPUS, Ansan-si (KR)

(72) Inventors: Tae Joo Park, Ansan-si (KR); Ji Won Han, Yongin-si (KR)

(73) Assignee: INDUSTRY-UNIVERSITY COOPERATION FOUNDATION HANYANG UNIVERSITY ERICA CAMPUS, Ansan-si (KR)

(21) Appl. No.: 18/308,903

(22) Filed: Apr. 28, 2023

Related U.S. Application Data
(63) Continuation of application No. PCT/KR2021/015420, filed on Oct. 29, 2021.

(30) Foreign Application Priority Data
Oct. 30, 2020 (KR) 10-2020-0143539

(51) Int. Cl. C23C 16/455; C23C 16/18; H01L 21/285; H01L 29/49

(52) U.S. Cl. CPC C23C 16/45553; C23C 16/18; H01L 21/28506; H01L 29/49

(57) ABSTRACT

An alloy thin film manufacturing method is provided. The alloy thin film manufacturing method may comprise the steps of: preparing a substrate; providing, onto the substrate, a first precursor comprising a first metal; and providing, onto the substrate onto which the first precursor has been provided, a second precursor comprising a second metal, so as to form an alloy thin film of the first metal and the second metal, obtained through the reaction of the first precursor and the second precursor.

### CROSS REFERENCE TO RELATED APPLICATIONS

This is a continuation of PCT/KR2021/015420 (filed 29 Oct. 2021), which claims the benefit of Republic of Korea Patent Application KR 10-2020-0143539 (filed 30 Oct. 2020). The entire disclosure of each of these priority applications is hereby incorporated by reference herein.

### TECHNICAL FIELD

The present invention relates to an alloy thin film and a manufacturing method therefor, and more particularly, to an alloy thin film and a manufacturing method therefor, which use atomic layer deposition (ALD).

### BACKGROUND ART

Currently, transistors used in various semiconductor elements use complementary metal-oxide-semiconductor (CMOS) structures for a leakage current and signal accuracy. CMOS refers to a transistor structure complementarily using both n-type and p-type semiconductors rather than using only one of the n-type and p-type semiconductors so as to extremely limit a leakage current that increases power consumption, improve signal reliability, and increase a degree of element integration. In order to drive a CMOS transistor, a material having a work function suitable for each semiconductor has to be applied to foam a channel in n-type and p-type semiconductor regions.

Meanwhile, recently, as semiconductor elements are continuously miniaturized to improve performance and a degree of integration, very small and complex structures are applied to elements. Thus, a required thickness of an electrode thin film for driving a transistor is also becoming very thin, so that it is becoming more difficult to select and deposit a metal material having suitable physical properties. Accordingly, researches on adjustment of physical properties of a thin film through control of a composition while a composite metal film is formed by using atomic layer deposition (ALD), which facilitates formation and integration the thin film, are being actively conducted. A single noble metal thin film or a composite noble metal thin film including the same has a high work function so as to be suitable as an electrode material for a p-type semiconductor, and a single non-noble metal thin film or a composite metal film including a non-noble metal has a low work function so as to be used as an electrode material for an n-type semiconductor. However, due to a low oxidation resistance, a non-noble metal having a low work function may necessarily involve a reduction step using a hydrogen-based material or unavoidably require deposition in the foam of a nitride by using a nitriding agent when deposited through conventional ALD, so that a process may be complicated, and adjustment of physical properties may be restricted.

Accordingly, various researches on a composite metal film (alloy thin film) that may be deposited by a simple scheme without involving a conventional reduction or nitriding step have been conducted.

### DISCLOSURE

### Technical Problem

One technical object of the present invention is to provide an alloy thin film and a manufacturing method therefor, capable of manufacturing an alloy thin film without a conventional reduction or nitriding step.

Another technical object of the present invention is to provide an alloy thin film having a higher step coverage than an alloy thin film formed by sputtering and chemical vapor deposition (CVD) processes, and a manufacturing method therefor.

Still another technical object of the present invention is to provide an alloy thin film having a lower ratio of oxygen than an alloy thin film formed by atomic layer deposition (ALD) by using a reaction gas including one of oxygen (O) and nitrogen (N), and a manufacturing method therefor.

Technical objects of the present invention are not limited to the technical objects described above.

### Technical Solution

To achieve the technical objects described above, according to the present invention, there is provided a method for manufacturing an alloy thin film.

According to one embodiment, the method for manufacturing the alloy thin film includes: preparing a substrate; providing a first precursor including a first metal onto the substrate; and forming an alloy thin film of the first metal and a second metal, which is obtained through a reaction of the first precursor and a second precursor, by providing the second precursor including the second metal onto the substrate onto which the first precursor is provided.

According to one embodiment, in the foaming of the alloy thin film, a ligand reactant, which is obtained through a reaction of a ligand of the first precursor and a ligand of the second precursor, may be removed from the substrate, and the first metal of the first precursor and the second metal of the second precursor may remain on the substrate.

According to one embodiment, the foaming of the alloy thin film may be performed without a reaction gas including one of oxygen (O) and nitrogen (N).

According to one embodiment, the alloy thin film may have a higher step coverage than an alloy thin film of the first metal and the second metal, which is formed by a sputtering process.

According to one embodiment, the alloy thin film may have a lower ratio of oxygen (O) than an alloy thin film of the first metal and the second metal, which is formed by using a reaction gas including one of oxygen (O) and nitrogen (N).

According to one embodiment, the first metal may include one of titanium (Ti), ruthenium (Ru), iridium (Ir), tantalum (Ta), aluminum (Al), and hafnium (Hf), and the second metal may include one of titanium (Ti), ruthenium (Ru), iridium (Ir), tantalum (Ta), aluminum (Al), and hafnium (Hf).

According to one embodiment, when the first metal includes titanium (Ti), a ligand of the first precursor may include dimethylamine.

According to one embodiment, when the first metal includes ruthenium (Ru), a ligand of the first precursor may include one of ethylbenzene and ethylcyclohexadiene.

According to one embodiment, when the first metal includes iridium (Ir), a ligand of the first precursor may include cyclopropanyl.

According to one embodiment, when the first metal includes tantalum (Ta), a ligand of the first precursor may include ethoxy.

According to one embodiment, when the first metal includes aluminum (Al), a ligand of the first precursor may include methyl.

According to one embodiment, when the first metal includes hafnium (Hf), a ligand of the first precursor may include ethylmethylamine.

To achieve the technical objects described above, according to the present invention, there is provided an alloy thin film.

According to one embodiment, the alloy thin film includes: a substrate; and an alloy thin film of a first metal and a second metal, which is disposed on the substrate, wherein a ratio (atomic %) of carbon (C) is higher than a ratio (atomic %) of oxygen (O) in the alloy thin film.

According to one embodiment, as a thickness of the alloy thin film increases, contents of the first metal and the second metal may be linearly increased.

### Advantageous Effects

According to an embodiment of the present invention, a method for manufacturing an alloy thin film may include: preparing a substrate; providing a first precursor including a first metal onto the substrate; and forming an alloy thin film of the first metal and a second metal, which is obtained through a reaction of the first precursor and a second precursor, by providing the second precursor including the second metal onto the substrate onto which the first precursor is provided.

In other words, according to the embodiment of the present invention, the alloy thin film may be formed by atomic layer deposition (ALD) without providing a reaction gas including one of oxygen (O) and nitrogen (N). Accordingly, the alloy thin film may have a lower ratio of oxygen (O) than an alloy thin film formed by the atomic layer deposition (ALD) by using the reaction gas including one of oxygen (O) and nitrogen (N), and may have a higher step coverage than an alloy thin film formed by a sputtering process.

In addition, according to the method for manufacturing the alloy thin film of the embodiment of the present invention, an alloy thin film may be formed without a conventional reduction or nitriding step, so that the method can be easily applied to a process of manufacturing an n-type MOS electrode thin film and a p-type MOS electrode thin film.

### DESCRIPTION OF DRAWINGS

FIG. 1 is a flowchart for describing a method for manufacturing an alloy thin film according to an embodiment of the present invention.

FIG. 2 is a view for describing a process of manufacturing an alloy thin film according to an embodiment of the present invention.

FIG. 3 is a view for describing a mechanism for manufacturing an alloy thin film according to an embodiment of the present invention.

FIG. 4 is a view for describing precursors that may be used in the process of manufacturing the alloy thin film according to the embodiment of the present invention.

FIG. 5 is a graph showing changes in contents of titanium and ruthenium in a thin film with respect to a process cycle of an alloy thin film according to Experimental Example 1 of the present invention.

FIG. 6 is a graph showing a change in a thickness of the thin film with respect to the process cycle of the alloy thin film according to Experimental Example 1 of the present invention.

FIG. 7 is a graph showing a result of measuring a resistivity with respect to a thickness of the alloy thin film according to Experimental Example 1 of the present invention.

FIG. 8 is a graph showing a change in a thickness of a thin film with respect to a process cycle of an alloy thin film according to Experimental Example 2 of the present invention.

FIG. 9 is a graph showing changes in contents of ruthenium and hafnium in the thin film with respect to the process cycle of the alloy thin film according to Experimental Example 2 of the present invention.

FIG. 10 is a graph showing a change in a thickness of a thin film with respect to a process cycle of an alloy thin film according to Experimental Example 3 of the present invention.

FIG. 11 is a graph showing changes in contents of iridium and titanium in the thin film with respect to the process cycle of the alloy thin film according to Experimental Example 3 of the present invention.

FIG. 12 is a graph showing a change in a thickness of a thin film with respect to a process cycle of an alloy thin film according to Experimental Example 4 of the present invention.

FIG. 13 is a graph showing changes in contents of iridium and hafnium in the thin film with respect to the process cycle of the alloy thin film according to Experimental Example 4 of the present invention.

FIG. 14 is a graph showing a change in a thickness of a thin film with respect to a process cycle of an alloy thin film according to Experimental Example 5 of the present invention.

FIG. 15 is a graph showing changes in contents of titanium and tantalum in the thin film with respect to the process cycle of the alloy thin film according to Experimental Example 5 of the present invention.

FIG. 16 is a graph showing a change in a thickness of a thin film with respect to a process cycle of a thin film according to Comparative Example 1 of the present invention.

FIG. 17 is a graph showing changes in contents of titanium and tantalum in the thin film with respect to the process cycle of the thin film according to Comparative Example 1 of the present invention.

FIG. 18 is a graph showing a change in a thickness of a thin film with respect to a process cycle of a thin film according to Comparative Example 2 of the present invention.

FIG. 19 is a graph showing changes in contents of ruthenium and aluminum in the thin film with respect to the process cycle of the thin film according to Comparative Example 2 of the present invention.

### MODE FOR INVENTION

Hereinafter, exemplary embodiments of the present invention will be described in detail with reference to the accompanying drawings. However, the technical idea of the present invention is not limited to the embodiments described herein, but may be realized in different forms. The embodiments introduced herein are provided to sufficiently deliver the idea of the present invention to those skilled in the art so that the disclosed contents may become thorough and complete.

When it is mentioned in the present disclosure that one element is on another element, it means that one element may be directly famed on another element, or a third element may be interposed between one element and another element. Further, in the drawings, thicknesses of films and regions are exaggerated for effective description of the technical contents.

In addition, in various embodiments of the present disclosure, the terms such as first, second, and third are used to describe various elements, but the elements are not limited by the terms. The terms are used only to distinguish one element from another element. Therefore, an element mentioned as a first element in one embodiment may be mentioned as a second element in another embodiment. The embodiments described and illustrated herein include their complementary embodiments. Further, the term “and/or” used herein is used to include at least one of the elements enumerated before and after the term.

As used herein, expressions in a singular form include a meaning of a plural form unless the context clearly indicates otherwise. Further, the terms such as “including” and “having” are intended to designate the presence of features, numbers, steps, elements, or combinations thereof described in the present disclosure, and shall not be construed to preclude any possibility of the presence or addition of one or more other features, numbers, steps, elements, or combinations thereof. In addition, the tam. “connection” used herein is used to include both indirect and direct connections of a plurality of elements.

Further, in the following description of the present invention, detailed descriptions of known functions or configurations incorporated herein will be omitted when they may make the gist of the present invention unnecessarily unclear.

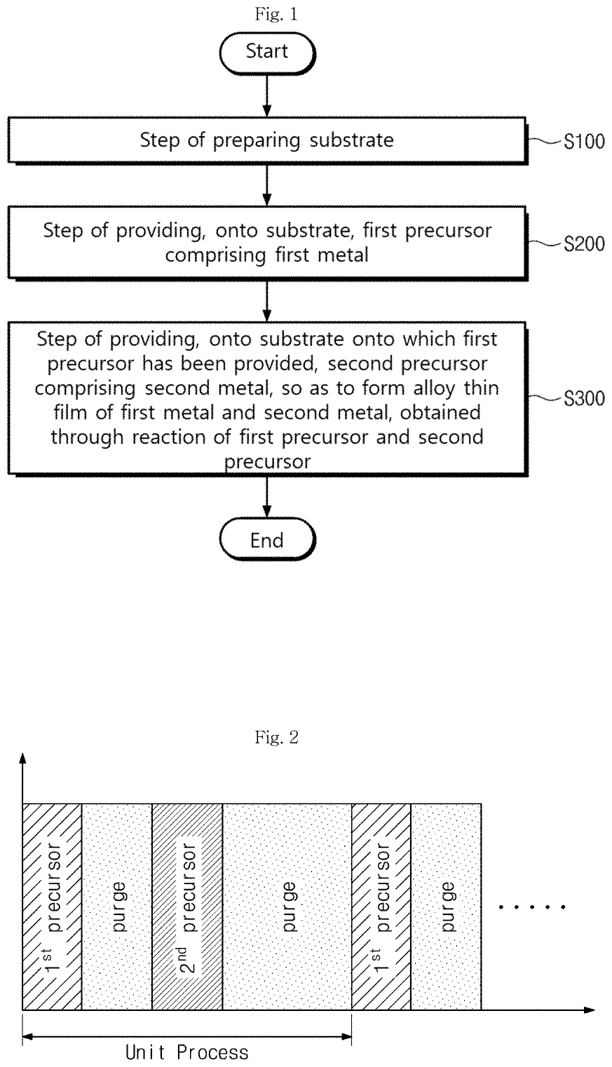

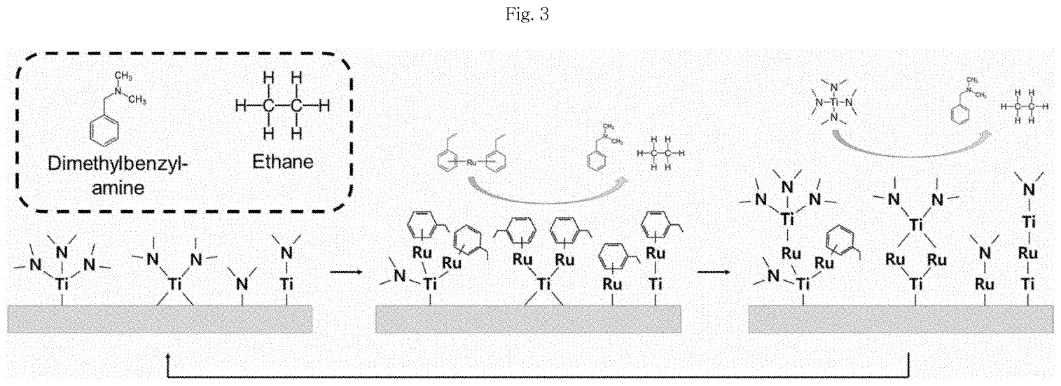

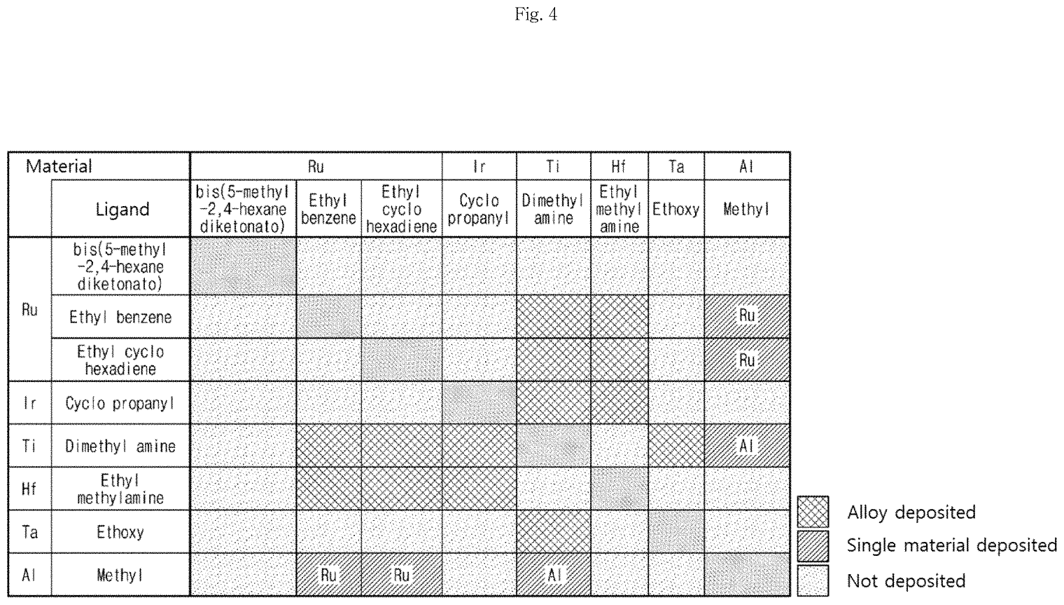

FIG. 1 is a flowchart for describing a method for manufacturing an alloy thin film according to an embodiment of the present invention, FIG. 2 is a view for describing a process of manufacturing an alloy thin film according to an embodiment of the present invention, FIG. 3 is a view for describing a mechanism for manufacturing an alloy thin film according to an embodiment of the present invention, and FIG. 4 is a view for describing precursors that may be used in the process of manufacturing the alloy thin film according to the embodiment of the present invention.

Referring to FIG. 1, according to an embodiment of the present invention, a method for manufacturing an alloy thin film may include: preparing a substrate (S100); providing a first precursor including a first metal onto the substrate (S200); and forming an alloy thin film of the first metal and a second metal, which is obtained through a reaction of the first precursor and a second precursor, by providing the second precursor including the second metal onto the substrate onto which the first precursor is provided (S300). According to one embodiment, the forming of the alloy thin film may be performed without a reaction gas including one of oxygen (O) and nitrogen (N).

In other words, according to the embodiment, the alloy thin film may be formed by atomic layer deposition (ALD) without providing the reaction gas including one of oxygen (O) and nitrogen (N). Accordingly, a ratio (atomic %) of carbon (C) may be higher than a ratio (atomic %) of oxygen (O) in the alloy thin film.

In more detail, as shown in FIG. 2, the alloy thin film may be formed by sequentially pertaining a first precursor provision step (1st precursor), a purge step (purge), a second precursor provision step (2nd precursor), and a purge step (purge). The first precursor provision step-purge step-second precursor provision step-purge step may be defined as a unit process, and the unit process may be repeatedly performed a plurality of times. Depending on a number of repetitions of the unit process, a thickness of the alloy thin film may be controlled. According to one embodiment, as the thickness of the alloy thin film increases, contents of the first metal and the second metal in the alloy thin film may be linearly increased.

When the second precursor is provided onto the substrate onto which the first precursor is provided, a ligand reactant may be generated through a reaction of a ligand of the first precursor and a ligand of the second precursor, and the generated ligand reactant may be removed from the substrate. Accordingly, the first metal and the second metal may remain on the substrate, so that the alloy thin film of the first metal and the second metal may be formed.

For example, as shown in FIG. 3, when TDMATi (tetrakis(dimethylamino)titanium) is used as the first precursor, and EBECHRu ((ethylbenzene) (1-ethyl-1,4-cyclohexadiene)ruthenium) is used as the second precursor, a dimethylamine ligand of the TDMATi may react with ethylbenzene and ethylcyclohexadiene (1-ethyl-1,4-cyclohexadiene) ligands of the EBECHRu to form dimethylbenzylamine and ethane, and the formed dimethylbenzylamine and the formed ethane may be removed from the substrate. Accordingly, titanium (Ti) and ruthenium (Ru) may remain on the substrate, so that a titanium (Ti)-ruthenium (Ru) alloy thin film may be formed.

As described above, the alloy thin film may be formed by the reaction of the ligand of the first precursor and the ligand of the second precursor, so that a first precursor and a second precursor, which have ligands between which a reaction easily occurs, may be used.

For example, as shown in FIG. 4, when a titanium (Ti) precursor having a dimethylamine ligand is used as the first precursor, a ruthenium (Ru) precursor having one of ethylbenzene and ethylcyclohexadiene ligands may be used as the second precursor. In detail, TDMATi (tetrakis(dimethylamino)titanium) may be used as the first precursor, and EBECHRu ((ethylbenzene) (1-ethyl-1,4-cyclohexadiene)ruthenium) may be used as the second precursor.

As another example, when a titanium (Ti) precursor having a dimethylamine ligand is used as the first precursor, an iridium (Ir) precursor having a cyclopropanyl ligand may be used as the second precursor. In detail, TDMATi (tetrakis(dimethylamino)titanium) may be used as the first precursor, and TICP ((tricarbonyl) (cyclopropanyl)iridium) may be used as the second precursor.

As still another example, when a titanium (Ti) precursor having a dimethylamine ligand is used as the first precursor, a tantalum (Ta) precursor having ethoxy may be used as the second precursor. In detail, TDMATi (tetrakis(dimethylamino)titanium) may be used as the first precursor, and PET (penta(ethoxy)tantalum) may be used as the second precursor.

As yet another example, when a hafnium (Hf) precursor having an ethylmethylamine ligand is used as the first precursor, a ruthenium (Ru) precursor having one of ethylbenzene and ethylcyclohexadiene ligands may be used as the second precursor. In detail, TEMAHf (tetrakis(ethylmethylamino)hafnium) may be used as the first precursor, and EBECHRu ((ethylbenzene) (1-ethyl-1,4-cyclohexadiene)ruthenium) may be used as the second precursor.

As still yet another example, when a hafnium (Hf) precursor having an ethylmethylamine ligand is used as the first precursor, an iridium (Ir) precursor having a cyclopropanyl ligand may be used as the second precursor. In detail, TEMAHf (tetrakis(ethylmethylamino)hafnium) may be used as the first precursor, and TICP ((tricarbonyl)(cyclopropanyl)iridium) may be used as the second precursor.

As a result, according to the embodiment of the present invention, the alloy thin film may be formed by atomic layer deposition (ALD) without providing a reaction gas including one of oxygen (O) and nitrogen (N). Accordingly, the alloy thin film may have a lower ratio of oxygen (O) than an alloy thin film formed by the atomic layer deposition (ALD) by using the reaction gas including one of oxygen (O) and nitrogen (N), and may have a higher step coverage than an alloy thin film formed by a sputtering process.

In addition, according to the method for manufacturing the alloy thin film of the embodiment of the present invention, an alloy thin film may be formed without a conventional reduction or nitriding step, so that the method may be easily applied to a process of manufacturing an n-type MOS electrode thin film and a p-type MOS electrode thin film.

The alloy thin film and the manufacturing method therefor according to the embodiment of the present invention have been described above. Hereinafter, specific experimental examples and characteristic evaluation results of the alloy thin film and the manufacturing method therefor according to the embodiment of the present invention will be described.

### Manufacture of Alloy Thin Film According to Experimental Example 1

An alloy thin film of a first metal included in a first precursor and a second metal included in a second precursor was prepared on a substrate by using first precursor provision step (12s)-purge step (10s)-second precursor provision step (25s)-purge step (60s).

In detail, an alloy thin film of titanium (Ti) and ruthenium (Ru) was prepared by using TDMATi (tetrakis(dimethylamino)titanium) as the first precursor and using EBECHRu ((ethylbenzene) (1-ethyl-1,4-cyclohexadiene)ruthenium) as the second precursor.

### Manufacture of Alloy Thin Film According to Experimental Example 2

The method for manufacturing the alloy thin film according to Experimental Example 1 described above was used, and an alloy thin film of ruthenium (Ru) and hafnium (Hf) was prepared by using EBECHRu ((ethylbenzene) (1-ethyl-1,4-cyclohexadiene)ruthenium) as the first precursor and using TEMAHf (tetrakis(ethylmethylamino)hafnium) as the second precursor. In addition, the first precursor provision step-purge step-second precursor provision step-purge step were performed for 10 seconds, 30 seconds, 10 seconds, and 30 seconds, respectively.

### Manufacture of Alloy Thin Film According to Experimental Example 3

The method for manufacturing the alloy thin film according to Experimental Example 2 described above was used, and an alloy thin film of iridium (Ir) and titanium (Ti) was prepared by using TICP ((tricarbonyl) (cyclopropanyl)iridium) as the first precursor and using TDMATi (tetrakis(dimethylamino)titanium) as the second precursor.

### Manufacture of Alloy Thin Film According to Experimental Example 4

The method for manufacturing the alloy thin film according to Experimental Example 2 described above was used, and an alloy thin film of iridium (Ir) and hafnium (Hf) was prepared by using TICP ((tricarbonyl) (cyclopropanyl)iridium) as the first precursor and using TEMAHf (tetrakis(ethylmethylamino)hafnium) as the second precursor.

### Manufacture of Alloy Thin Film According to Experimental Example 5

The method for manufacturing the alloy thin film according to Experimental Example 2 described above was used, and an alloy thin film of titanium (Ti) and tantalum (Ta) was prepared by using TDMATi (tetrakis(dimethylamino)titanium) as the first precursor and using PET (penta(ethoxy)tantalum) as the second precursor.

### Manufacture of Thin Film According to Comparative Example 1

The method for manufacturing the alloy thin film according to Experimental Example 2 described above was used, wherein TDMATi (tetrakis(dimethylamino)titanium) was used as the first precursor, and TMA (trimethylaluminium) was used as the second precursor. Although mutually different metal precursors were used, a single thin film of aluminum (Al) was famed.

### Manufacture of Thin Film According to Comparative Example 2

The method for manufacturing the alloy thin film according to Experimental Example 2 described above was used, wherein EBECHRu ((ethylbenzene) (1-ethyl-1,4-cyclohexadiene)ruthenium) was used as the first precursor, and TMA (trimethylaluminium) was used as the second precursor. Although mutually different metal precursors were used, a single thin film of ruthenium (Ru) was formed.

Results of the precursors used in manufacturing processes and the formed thin films according to the experimental examples and the comparative examples described above are summarized through [Table 1] below.

TABLE 1

| Classifi- | First | Second | |
|---|---|---|---|
| cation | precursor | precursor | Formed thin film |
| Experimental | TDMATi | EBECHRu | Titanium (Ti)-ruthenium (Ru) |
| Example 1 | (Ti) | (Ru) | alloy thin film |
| Experimental | EBECHRu | TEMAHf | Ruthenium (Ru)-hafnium (Hf) |
| Example 2 | (Ru) | (Hf) | alloy thin film |
| Experimental | TICP (Ir) | TDMATi | Iridium (Ir)-titanium (Ti) |
| Example 3 | | (Ti) | alloy thin film |
| Experimental | TICP (Ir) | TEMAHf | Iridium (Ir)-hafnium (Hf) |
| Example 4 | | (Hf) | alloy thin film |
| Experimental | TDMATi | PET (Ta) | Titanium (Ti)-tantalum (Ta) |
| Example 5 | (Ti) | | alloy thin film |
| Comparative | TDMATi | TMA (Al) | Aluminum (Al) single film |
| Example 1 | (Ti) | | |
| Comparative | EBECHRu | TMA (Al) | Ruthenium (Ru) single film |
| Example 2 | (Ru) | | |

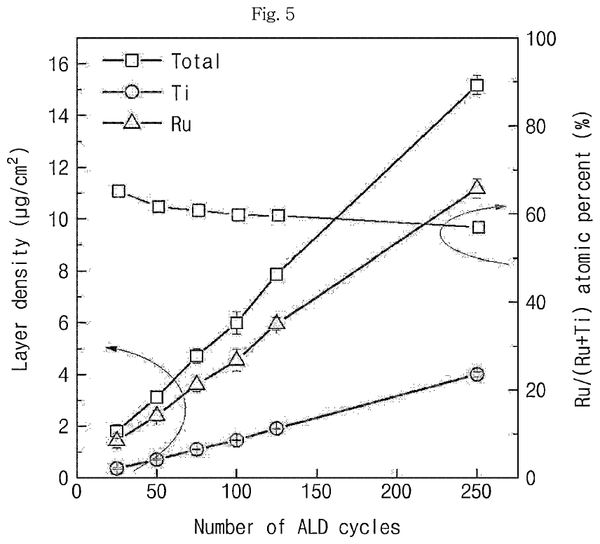

FIG. 5 is a graph showing changes in contents of titanium and ruthenium in a thin film with respect to a process cycle of an alloy thin film according to Experimental Example 1 of the present invention.

Referring to FIG. 5, first precursor provision step (12s) purge step (10s)-second precursor provision step (25s)-purge step (60s) were defined as one cycle, and contents (Layer density, μg/cm²) of titanium (Ti) and ruthenium (Ru) in the formed alloy thin film were measured as a number of cycles increases. In detail, the contents in the thin film were measured through WDXRF. As shown in FIG. 5, it was found that the contents of titanium (Ti) and ruthenium (Ru) in the alloy thin film are linearly increased as the number of cycles increases. Accordingly, it was found that the alloy thin film according to Experimental Example 1 exhibits a general behavior of atomic layer deposition (ALD).

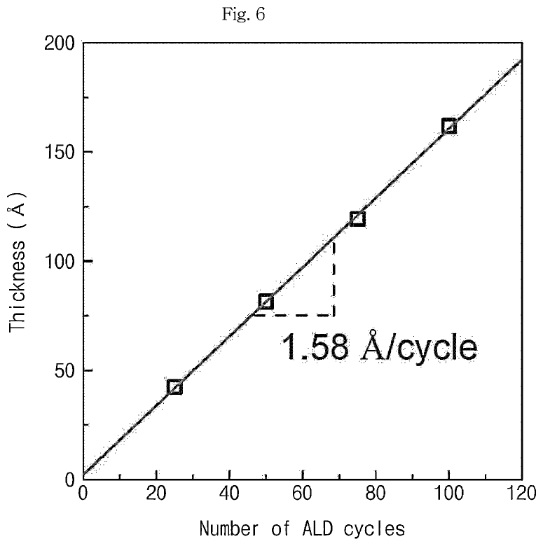

FIG. 6 is a graph showing a change in a thickness of the thin film with respect to the process cycle of the alloy thin film according to Experimental Example 1 of the present invention.

Referring to FIG. 6, first precursor provision step (12s)-purge step (10s)-second precursor provision step (25s)-purge step (60s) were defined as one cycle, and a thickness of the formed alloy thin film was measured as a number of cycles increases. In detail, the thickness of the alloy thin film was measured through spectroscopic ellipsometry. As shown in FIG. 6, it was found that the thickness of the alloy thin film is linearly increased as the number of cycles increases. Accordingly, it was found that the alloy thin film according to Experimental Example 1 exhibits a general behavior of atomic layer deposition (ALD).

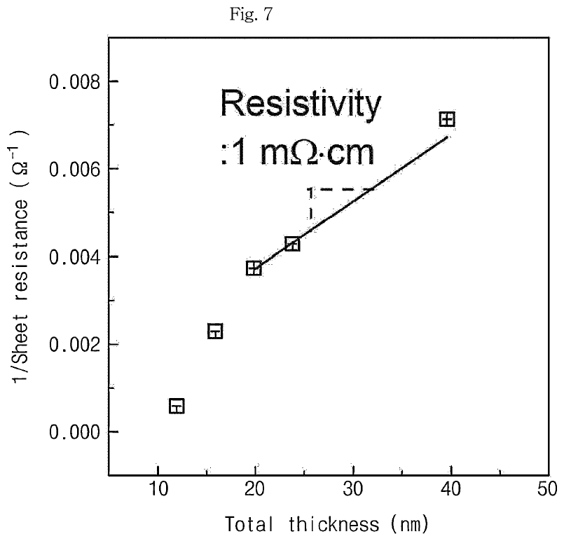

FIG. 7 is a graph showing a result of measuring a resistivity with respect to a thickness of the alloy thin film according to Experimental Example 1 of the present invention.

Referring to FIG. 7, a resistivity (1/Sheet resistance, Ω⁻¹) according to a thickness (Total thickness, nm) of the alloy thin film according to Experimental Example 1 was measured and shown. As shown in FIG. 7, it was found that the alloy thin film according to Experimental Example 1 has a low resistivity of 1 mΩ·cm. Accordingly, it was verified that a metal thin film is formed. In detail, the resistivity of the alloy thin film was measured through a 4-point probe method using a Van der Pauw configuration.

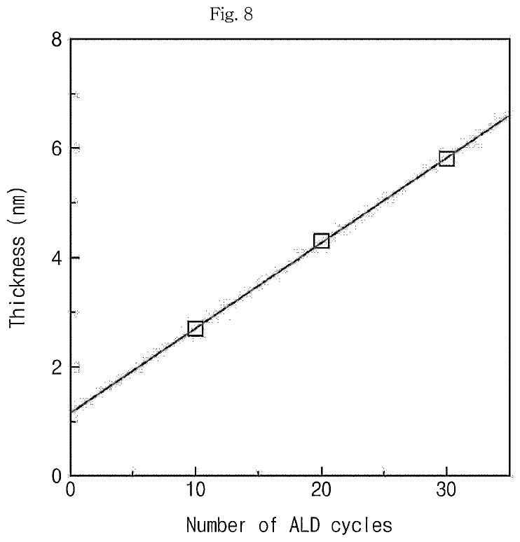

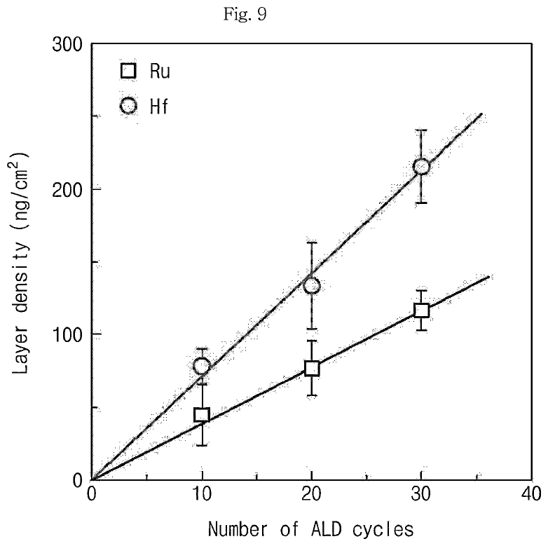

FIG. 8 is a graph showing a change in a thickness of a thin film with respect to a process cycle of an alloy thin film according to Experimental Example 2 of the present invention, and FIG. 9 is a graph showing changes in contents of ruthenium and hafnium in the thin film with respect to the process cycle of the alloy thin film according to Experimental Example 2 of the present invention.

Referring to FIG. 8, first precursor provision step (10s)-purge step (30s)-second precursor provision step (10s)-purge step (30s) were defined as one cycle, and a thickness of the formed alloy thin film was measured as a number of cycles increases. In detail, the thickness of the alloy thin film was measured through spectroscopic ellipsometry. As shown in FIG. 8, it was found that the thickness of the alloy thin film is linearly increased as the number of cycles increases. Accordingly, it was found that the alloy thin film according to Experimental Example 2 exhibits a general behavior of atomic layer deposition (ALD).

Referring to FIG. 9, first precursor provision step (10s)-purge step (30s)-second precursor provision step (10s)-purge step (30s) were defined as one cycle, and contents (Layer density, μg/cm²) of ruthenium (Ru) and hafnium (Hf) in the formed alloy thin film were measured as a number of cycles increases. In detail, the contents in the thin film were measured through WDXRF. As shown in FIG. 9, it was found that the contents of ruthenium (Ru) and hafnium (Hf) in the alloy thin film are linearly increased as the number of cycles increases. Accordingly, it was found that the alloy thin film according to Experimental Example 2 exhibits a general behavior of atomic layer deposition (ALD).

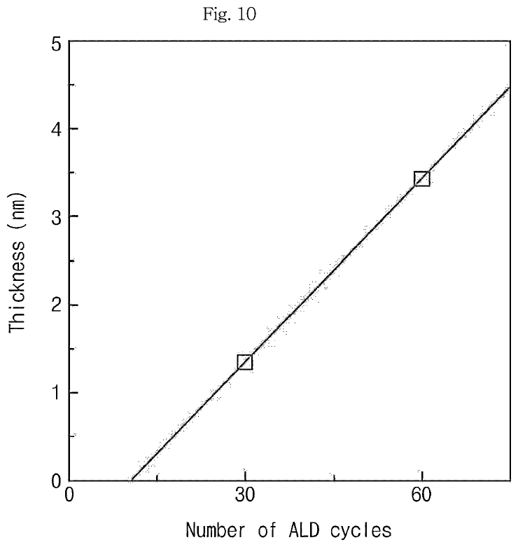

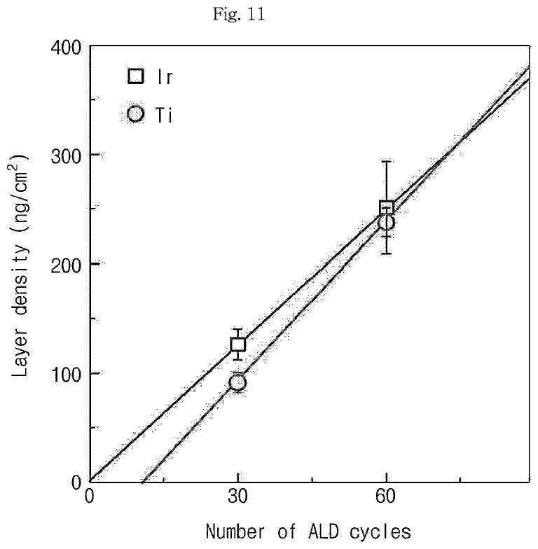

FIG. 10 is a graph showing a change in a thickness of a thin film with respect to a process cycle of an alloy thin film according to Experimental Example 3 of the present invention, and FIG. 11 is a graph showing changes in contents of iridium and titanium in the thin film with respect to the process cycle of the alloy thin film according to Experimental Example 3 of the present invention.

Referring to FIG. 10, first precursor provision step (10s)-purge step (30s)-second precursor provision step (10s)-purge step (30s) were defined as one cycle, and a thickness of the formed alloy thin film was measured as a number of cycles increases. In detail, the thickness of the alloy thin film was measured through spectroscopic ellipsometry. As shown in FIG. 10, it was found that the thickness of the alloy thin film is linearly increased as the number of cycles increases. Accordingly, it was found that the alloy thin film according to Experimental Example 3 exhibits a general behavior of atomic layer deposition (ALD).

Referring to FIG. 11, first precursor provision step (10s)-purge step (30s)-second precursor provision step (10s)-purge step (30s) were defined as one cycle, and contents (Layer density, μg/cm²) of iridium (Ir) and titanium (Ti) in the formed alloy thin film were measured as a number of cycles increases. In detail, the contents in the thin film were measured through WDXRF. As shown in FIG. 11, it was found that the contents of iridium (Ir) and titanium (Ti) in the alloy thin film are linearly increased as the number of cycles increases. Accordingly, it was found that the alloy thin film according to Experimental Example 3 exhibits a general behavior of atomic layer deposition (ALD).

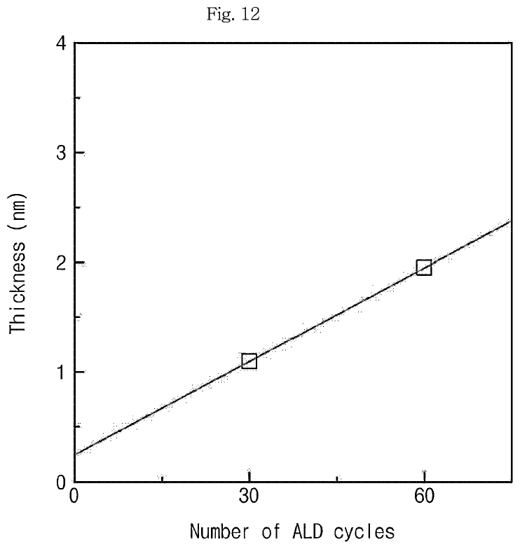

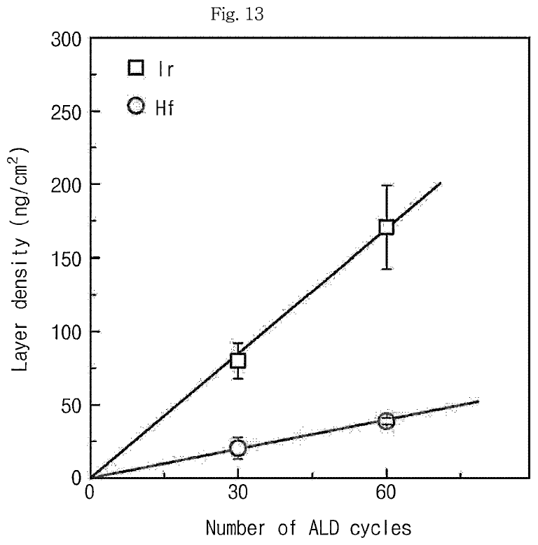

FIG. 12 is a graph showing a change in a thickness of a thin film with respect to a process cycle of an alloy thin film according to Experimental Example 4 of the present invention, and FIG. 13 is a graph showing changes in contents of iridium and hafnium in the thin film with respect to the process cycle of the alloy thin film according to Experimental Example 4 of the present invention.

Referring to FIG. 12, first precursor provision step (10s)-purge step (30s)-second precursor provision step (10s)-purge step (30s) were defined as one cycle, and a thickness of the formed alloy thin film was measured as a number of cycles increases. In detail, the thickness of the alloy thin film was measured through spectroscopic ellipsometry. As shown in FIG. 12, it was found that the thickness of the alloy thin film is linearly increased as the number of cycles increases. Accordingly, it was found that the alloy thin film according to Experimental Example 4 exhibits a general behavior of atomic layer deposition (ALD).

Referring to FIG. 13, first precursor provision step (10s)-purge step (30s)-second precursor provision step (10s)-purge step (30s) were defined as one cycle, and contents (Layer density, μg/cm²) of iridium (Ir) and hafnium (Hf) in the formed alloy thin film were measured as a number of cycles increases. In detail, the contents in the thin film were measured through WDXRF. As shown in FIG. 13, it was found that the contents of iridium (Ir) and hafnium (Hf) in the alloy thin film are linearly increased as the number of cycles increases. Accordingly, it was found that the alloy thin film according to Experimental Example 4 exhibits a general behavior of atomic layer deposition (ALD).

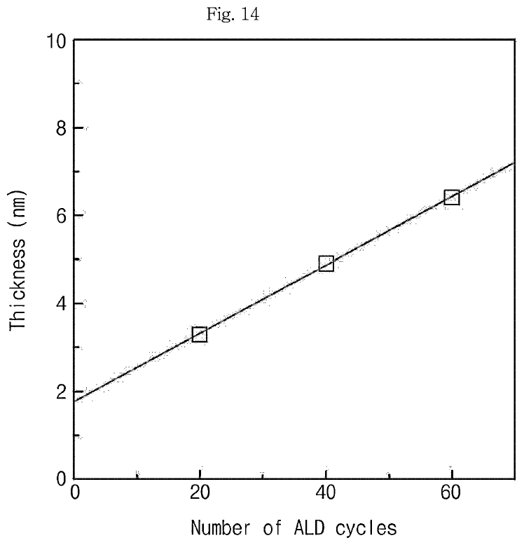

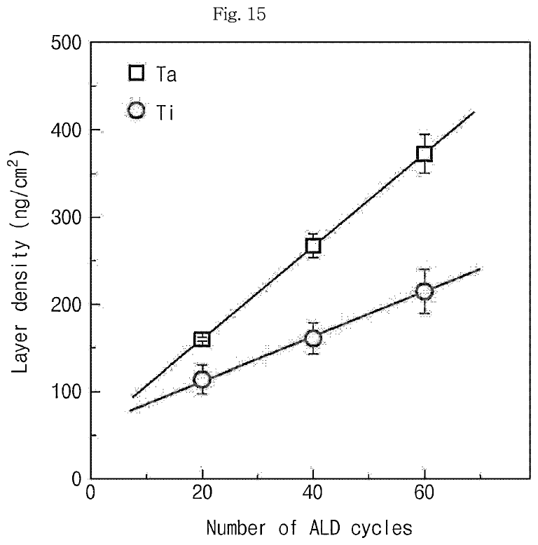

FIG. 14 is a graph showing a change in a thickness of a thin film with respect to a process cycle of an alloy thin film according to Experimental Example 5 of the present invention, and FIG. 15 is a graph showing changes in contents of titanium and tantalum in the thin film with respect to the process cycle of the alloy thin film according to Experimental Example 5 of the present invention.

Referring to FIG. 14, first precursor provision step (10s)-purge step (30s)-second precursor provision step (10s)-purge step (30s) were defined as one cycle, and a thickness of the formed alloy thin film was measured as a number of cycles increases. In detail, the thickness of the alloy thin film was measured through spectroscopic ellipsometry. As shown in FIG. 14, it was found that the thickness of the alloy thin film is linearly increased as the number of cycles increases. Accordingly, it was found that the alloy thin film according to Experimental Example 5 exhibits a general behavior of atomic layer deposition (ALD).

Referring to FIG. 15, first precursor provision step (10s)-purge step (30s)-second precursor provision step (10s)-purge step (30s) were defined as one cycle, and contents (Layer density, μg/cm²) of titanium (Ti) and tantalum (Ta) in the formed alloy thin film were measured as a number of cycles increases. In detail, the contents in the thin film were measured through WDXRF. As shown in FIG. 15, it was found that the contents of titanium (Ti) and tantalum (Ta) in the alloy thin film are linearly increased as the number of cycles increases. Accordingly, it was found that the alloy thin film according to Experimental Example 5 exhibits a general behavior of atomic layer deposition (ALD).

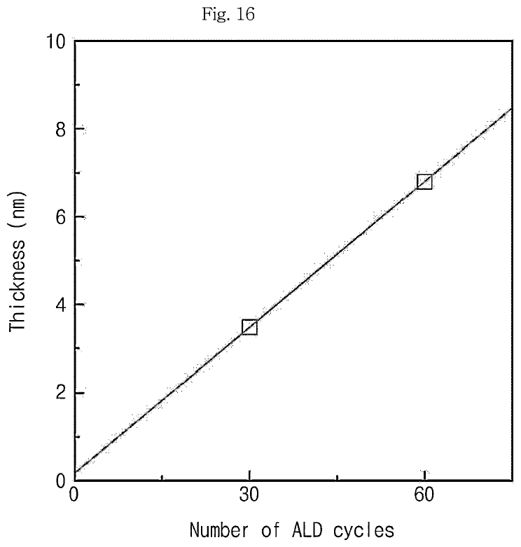

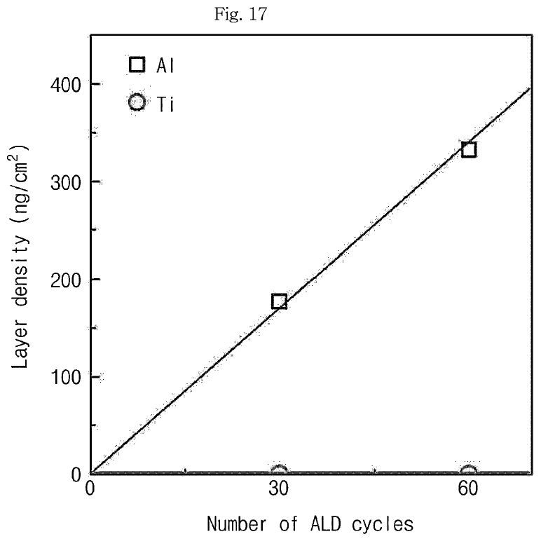

FIG. 16 is a graph showing a change in a thickness of a thin film with respect to a process cycle of a thin film according to Comparative Example 1 of the present invention, and FIG. 17 is a graph showing changes in contents of titanium and tantalum in the thin film with respect to the process cycle of the thin film according to Comparative Example 1 of the present invention.

Referring to FIG. 16, first precursor provision step (10s)-purge step (30s)-second precursor provision step (10s)-purge step (30s) were defined as one cycle, and a thickness of the formed alloy thin film was measured as a number of cycles increases. In detail, the thickness of the alloy thin film was measured through spectroscopic ellipsometry. As shown in FIG. 16, it was found that the thickness of the alloy thin film is linearly increased as the number of cycles increases. Accordingly, it was found that the alloy thin film according to Comparative Example 1 exhibits a general behavior of atomic layer deposition (ALD).

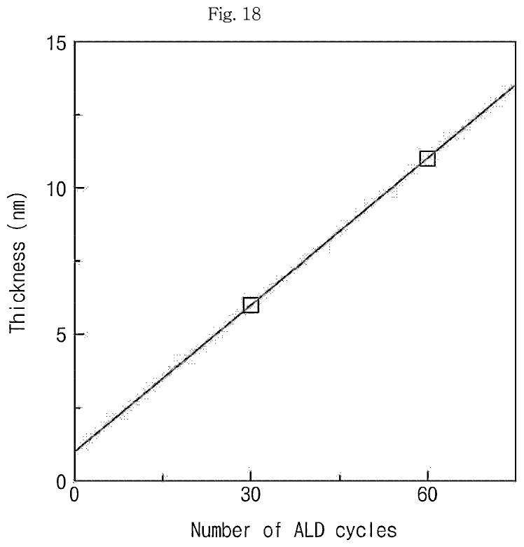

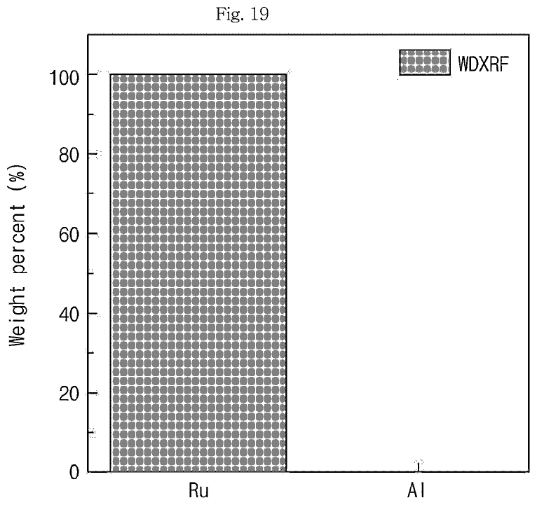

Referring to FIG. 17, first precursor provision step (10s)-purge step (30s)-second precursor provision step (10s)-purge step (30s) were defined as one cycle, and contents (Layer density, μg/cm²) of titanium (Ti) and aluminum (Al) in the formed alloy thin film were measured as a number of cycles increases. In detail, the contents in the thin film were measured through WDXRF. As shown in FIG. 17, it was found that a single film of aluminum (Al) is formed when TDMATi is used as the first precursor, and TMA is used as the second precursor. FIG. 18 is a graph showing a change in a thickness of a thin film with respect to a process cycle of a thin film according to Comparative Example 2 of the present invention, and FIG. 19 is a graph showing changes in contents of ruthenium and aluminum in the thin film with respect to the process cycle of the thin film according to Comparative Example 2 of the present invention.

Referring to FIG. 18, first precursor provision step (10s)-purge step (30s)-second precursor provision step (10s)-purge step (30s) were defined as one cycle, and a thickness of the formed alloy thin film was measured as a number of cycles increases. In detail, the thickness of the alloy thin film was measured through spectroscopic ellipsometry. As shown in FIG. 18, it was found that the thickness of the alloy thin film is linearly increased as the number of cycles increases. Accordingly, it was found that the alloy thin film according to Comparative Example 2 exhibits a general behavior of atomic layer deposition (ALD).

Referring to FIG. 19, first precursor provision step (10s)-purge step (30s)-second precursor provision step (10s)-purge step (30s) were defined as one cycle, and contents (Layer density, μg/cm²) of ruthenium (Ru) and aluminum (Al) in the formed alloy thin film were measured as a number of cycles increases. In detail, the contents in the thin film were measured through WDXRF. As shown in FIG. 19, it was found that a single film of ruthenium (Ru) is formed when EBECHRu is used as the first precursor, and TMA is used as the second precursor.

Although the exemplary embodiments of the present invention have been described in detail above, the scope of the present invention is not limited to a specific embodiment, and shall be interpreted by the appended claims. In addition, it is to be understood by those of ordinary skill in the art that various changes and modifications can be made without departing from the scope of the present invention.

### INDUSTRIAL APPLICABILITY

An alloy thin film and a manufacturing method therefor according to an embodiment of the present invention may be applied to the semiconductor field.

1. A method for manufacturing an alloy thin film, the method comprising:
preparing a substrate;
providing a first precursor including a first metal onto the substrate; and
forming an alloy thin film of the first metal and a second metal, which is obtained through a reaction of the first precursor and a second precursor, by providing the second precursor including the second metal onto the substrate onto which the first precursor is provided.

2. The method of claim 1, wherein, in the forming of the alloy thin film, a ligand reactant, which is obtained through a reaction of a ligand of the first precursor and a ligand of the second precursor, is removed from the substrate, and the first metal of the first precursor and the second metal of the second precursor remain on the substrate.

3. The method of claim 1, wherein the forming of the alloy thin film is performed without a reaction gas including one of oxygen (O) and nitrogen (N).

4. The method of claim 1, wherein the alloy thin film has a higher step coverage than an alloy thin film of the first metal and the second metal, which is formed by a sputtering process.

5. The method of claim 1, wherein the alloy thin film has a lower ratio of oxygen (O) than an alloy thin film of the first metal and the second metal, which is foiled by using a reaction gas including one of oxygen (O) and nitrogen (N).

6. The method of claim 1, wherein the first metal includes one of titanium (Ti), ruthenium (Ru), iridium (Ir), tantalum (Ta), aluminum (Al), and hafnium (Hf), and
the second metal includes one of titanium (Ti), ruthenium (Ru), iridium (Ir), tantalum (Ta), aluminum (Al), and hafnium (Hf).

7. The method of claim 6, wherein, when the first metal includes titanium (Ti), a ligand of the first precursor includes dimethylamine.

8. The method of claim 6, wherein, when the first metal includes ruthenium (Ru), a ligand of the first precursor includes one of ethylbenzene and ethylcyclohexadiene.

9. The method of claim 6, wherein, when the first metal includes iridium (Ir), a ligand of the first precursor includes cyclopropanyl.

10. The method of claim 6, wherein, when the first metal includes tantalum (Ta), a ligand of the first precursor includes ethoxy.

11. The method of claim 6, wherein, when the first metal includes aluminum (Al), a ligand of the first precursor includes methyl.

12. The method of claim 6, wherein, when the first metal includes hafnium (Hf), a ligand of the first precursor includes ethylmethylamine.

13. An alloy thin film comprising:
a substrate; and
an alloy thin film of a first metal and a second metal, which is disposed on the substrate,
wherein a ratio (atomic %) of carbon (C) is higher than a ratio (atomic %) of oxygen (O) in the alloy thin film.

14. The alloy thin film of claim 13, wherein, as a thickness of the alloy thin film increases, contents of the first metal and the second metal are linearly increased.
